(19) United States
(12) Patent Application Publication
(10) Pub. No.: US 2009/0179708 A1
(43) Pub. Date: Jul. 16, 2009

(54) PHASE LOCK OSCILLATOR AND WIRELESS COMMUNICATIONS DEVICE INCLUDING PHASE LOCK OSCILLATOR

(75) Inventor: Tetsuro Tamura, Kawasaki (JP)

Correspondence Address: Fujitsu Patent Center;C/O CPA Global, P.O. Box 52050, Minneapolis, MN, 55402, US

(73) Assignee: FUJITSU LIMITED, Kawasaki (JP)

(21) Appl. No.: 12/350,246

(22) Filed: Jan. 8, 2009

(30) Foreign Application Priority Data
Jan. 15, 2008 (JP) 2008-005970

(51) Int. Cl. H03L 7/00; H03L 7/099

(52) U.S. Cl. 331/34; 331/1 R

(57) ABSTRACT

A phase locked oscillator includes a voltage control oscillator and a phase comparator for detecting a phase difference between a phase of an output signal of the voltage control oscillator and a phase of a reference signal and controlling a voltage to be applied to the voltage control oscillator based on the detected phase difference. The phase locked oscillator also includes a delay control part configured to apply a variable delay time to the output signal of the voltage control oscillator and a delay time controlling part configured to control the delay time according to the detected phase difference.

### BACKGROUND OF THE INVENTION

1. Field of the Invention

The present invention generally relates to a phase lock oscillator and a wireless communications device including the phase lock oscillator.

2. Description of the Related Art

Oscillators used for wireless communication devices are required to provide frequency with higher precision as the efficiency of frequency use in wireless communications becomes higher. For example, an oscillator used for a digital modulation method such as OFDM (Orthogonal Frequency Division Multiplexing) is required to control phase error to 1° or less so that modulation and demodulation error can be prevented.

Normally, a PLL (Phase Locked Loop) is used as a frequency synthesizer. A basic configuration of a PLL 10 according to a related art example is illustrated in FIG. 1. The PLL 10 includes a phase comparator 2, a loop filter 4, a VCO (Voltage Controlled Oscillator) 6, and a divider 8.

A signal output from the VCO 6 and divided by the divider 8 and a reference signal of a reference frequency f_{ref} generated by an oscillator (e.g., crystal oscillator) are input to the phase comparator 2. The phase comparator 2 compares a phase of the signal output from the VCO 6 and divided by the divider 8 and a phase of the reference signal. In a case where one of the phases is different from the other, the phase comparator 2 generates a pulse signal (voltage) corresponding to the phase difference and outputs the generated pulse signal to the loop filter 4. The loop filter 4 removes high frequency components from the generated pulse signal (voltage) and outputs the signal (voltage) to the VCO 6. The loop filter 4 is configured as, for example, a low pass filter. The signal (voltage) output from the low pass filter 4 is input to a control voltage terminal of the VCO 6. The VCO 6 controls an oscillation frequency of its output pulse according to the voltage input to the VCO 6. In the PLL 10, the signal output from the VCO 6 and the reference signal have the same frequency when control voltage becomes constant by a feedback operation and the phase difference becomes a certain locked state. By reducing the frequency of the output of the VCO 6 to 1/N (N being an integer satisfying a relationship of N>0) with the divider 8 and inputting the signal with the reduced frequency to the phase comparator 2, the VCO 6 can be locked to a frequency that is N times of the reference frequency f_{ref}.

The signal output from the PLL includes phase noise. The phase noise includes noise caused by the input reference signal of the reference frequency, the phase noise of the VCO 6 as well as the noise generated from the phase comparator 2 and the loop filter 4. The noise caused by the input reference signal of the reference frequency and the noise generated from the phase comparator 2 can be attenuated by the loop filter 4. On the other hand, the phase noise of the VCO 6 can be reduced by broadening the bandwidth of the loop filter 4. Therefore, in order to reduce the phase noise of the VCO 6, it is necessary to optimize the filtering characteristic of the loop filter 4. Furthermore, in addition to preventing noise in each circuit, it is also necessary to take measures such as stabilizing the power source and preventing noise of one circuit being mixed with noise from another circuit.

For example, Japanese Laid-Open Patent Application No. 2000-49597 discloses a PLL circuit that controls (adjusts) the amount of current by using a calibration circuit that optimizes the current of the PLL circuit, to thereby eliminate process variation.

However, with the above-described related art example, there is a problem in which the loop filter 4 is unable to remove both the phase noise of the VCO6 and the noise caused by the input reference signal of the reference frequency. It is, therefore, necessary to carefully design the PLL 10 in order to prevent noise from being generated in each circuit. However, even if the PLL 10 is carefully designed, noise cannot be completely eliminated. Furthermore, the actual device on which the PLL is mounted is subject to noise from external circuits and changes of voltage of the power source. This causes the frequency of the PLL 10 to change and leads to degradation of modulation and demodulation precision.

### SUMMARY OF THE INVENTION

The present invention may provide a phase lock oscillator and a wireless communications device including the phase lock oscillator that substantially obviate one or more of the problems caused by the limitations and disadvantages of the related art.

Features and advantages of the present invention will be set forth in the description which follows, and in part will become apparent from the description and the accompanying drawings, or may be learned by practice of the invention according to the teachings provided in the description. Objects as well as other features and advantages of the present invention will be realized and attained by a phase lock oscillator and a wireless communications device including the phase lock oscillator particularly pointed out in the specification in such full, clear, concise, and exact terms as to enable a person having ordinary skill in the art to practice the invention.

To achieve these and other advantages and in accordance with the purpose of the invention, as embodied and broadly described herein, an embodiment of the invention provides a phase locked oscillator including a voltage control oscillator and a phase comparator for detecting a phase difference between a phase of an output signal of the voltage control oscillator and a phase of a reference signal and controlling a voltage to be applied to the voltage control oscillator based on the detected phase difference, including: a delay control part configured to apply a variable delay time to the output signal of the voltage control oscillator; and a delay time controlling part configured to control the delay time according to the detected phase difference.

Furthermore, another embodiment of the present invention provides a wireless communications device including: a phase locked oscillator including a voltage control oscillator, a phase comparator for detecting a phase difference between a phase of an output signal of the voltage control oscillator and a phase of a reference signal and controlling a voltage to be applied to the voltage control oscillator based on the detected phase difference, a delay control part configured to apply a variable delay time to the output signal of the voltage control oscillator, and a delay time controlling part configured to control the delay time according to the detected phase difference.

Other objects and further features of the present invention will be apparent from the following detailed description when read in conjunction with the accompanying drawings.

### BRIEF DESCRIPTION OF THE DRAWINGS

FIG. 1 is a block diagram illustrating a PLL according to a related art example;

FIG. 2 is a block diagram illustrating a phase locked oscillator according to an embodiment of the present invention;

FIG. 3 is a graph for describing a relationship between phase difference and delay time;

FIG. 4 is another graph for describing a relationship between phase difference and delay time;

FIG. 5 is a schematic diagram illustrating an example of a delay circuit of a phase locked oscillator according to an embodiment of the present invention;

FIG. 6 is a schematic diagram illustrating phase change corrected by a phase locked oscillator according to an embodiment of the present invention;

FIG. 7 is a schematic diagram illustrating an operation of a phase locked oscillator according to an embodiment of the present invention;

FIG. 8 is a block diagram illustrating a phase locked oscillator according to another embodiment of the present invention;

FIG. 9 is a graph for describing voltage output from a phase comparator with respect to phase difference in a phase locked oscillator according to an embodiment of the present invention;

FIG. 10 is a graph for describing oscillation frequency of a VCO with respect to input voltage in a phase locked oscillator according to an embodiment of the present invention;

FIG. 11 is a graph for describing delay output from a delay circuit with respect to input voltage in a phase locked oscillator according to an embodiment of the present invention;

FIG. 12 is a graph for describing an example of an operation of a phase locked oscillator according to an embodiment of the present invention;

FIG. 13 is another graph for describing an example of an operation of a phase locked oscillator according to an embodiment of the present invention;

FIG. 14 is a flowchart illustrating an example of an operation of a phase locked oscillator according to an embodiment of the present invention;

FIG. 15 is a block diagram illustrating a phase locked oscillator according to yet another embodiment of the present invention; and

FIG. 16 is a block diagram illustrating a phase locked oscillator according to yet another embodiment of the present invention.

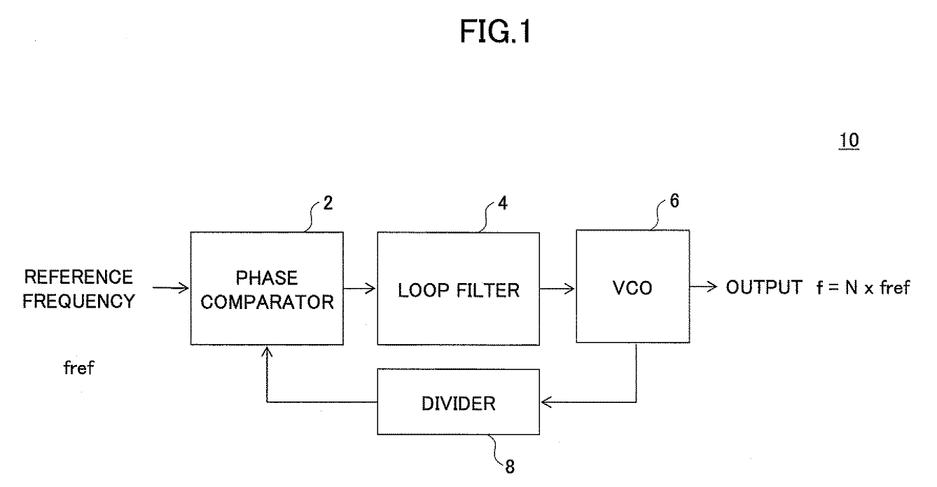

### DESCRIPTION OF THE PREFERRED EMBODIMENTS

In the following, embodiments of the present invention will be described with reference to the accompanying drawings.

### First Embodiment

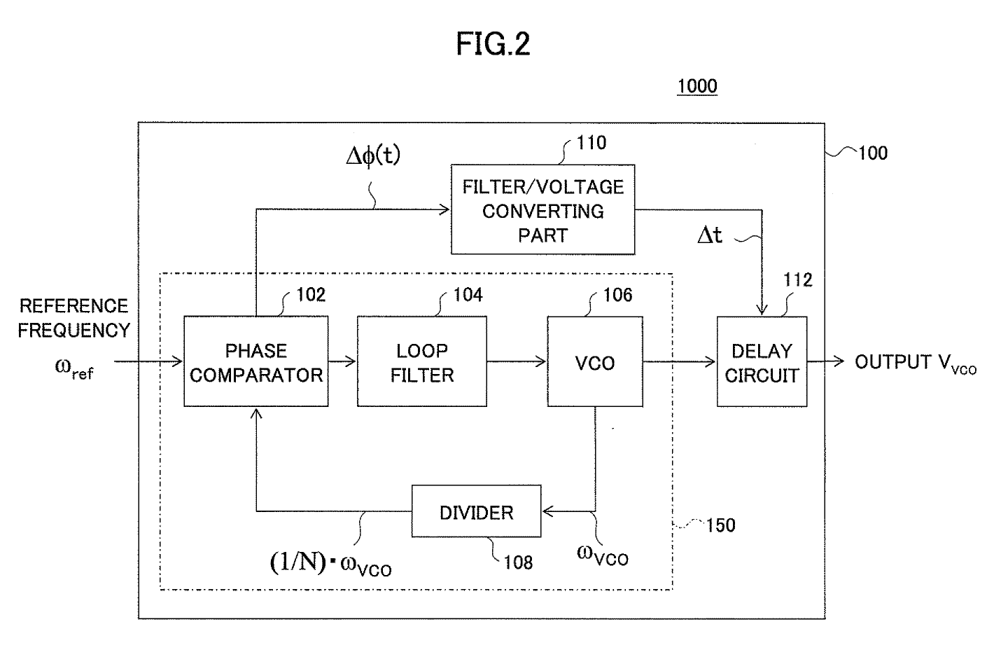

First, a phase lock oscillator (may also be referred to as “local oscillator” or “frequency synthesizer”) 100 according to the first embodiment of the present invention is described with reference to FIG. 2.

In this embodiment, the phase lock oscillator 100 is mounted on, for example, a wireless communications device 1000. That is, the wireless communication device 1000 includes the phase lock oscillator 100.

The phase lock oscillator 100 includes a phase comparator 102. A signal output from a VCO 106 and divided by a divider 108 and a reference signal of a reference frequency f_{ref} (reference angular frequency ω_{ref}) are input to the phase comparator 102. The reference signal is generated by an oscillator (e.g., crystal oscillator). The phase comparator 2 compares a phase of the signal output from the VCO 106 and divided by the divider 108 and a phase of the reference signal. In a case where the phases are different, the phase comparator 102 generates a voltage and a current corresponding to the phase difference. A pulse signal of the generated voltage (voltage pulse signal) generated by the phase comparator 102 is input to a filter/voltage converting part 110. Further, a pulse signal of the generated current (current pulse signal) generated by the phase comparator 102 is input to a loop filter 104 (described below).

For example, a reference signal V_{ref}(t) having a reference frequency expressed by the following Formula (1) is input to the phase comparator 102.

Vref=sin ω_{ref}t (Formula (1))

Furthermore, a signal Vvco (t) is output from the VCO 106 and expressed by the following Formula (2). In Formula (2), ω_{vco} is an angular frequency of a signal V_{vco}(t) output from the VCO 106.

V_{vco}(t)=sin (∫^{t}ω_{vco}dt) (Formula (2))

The phase comparator 102 is configured to detect phase difference between the reference signal and the signal output from the VCO 106. The phase difference Δφ output from the phase comparator 102 is expressed with the following Formula (3).

Δφ(t)=(1/N)˜^{t}ω_{vco}dt−ω_{ref}t (Formula (3))

The phase lock oscillator 100 according to an embodiment of the present invention also includes the loop filter 104. The loop filter 104 includes, for example, a low pass filter. The loop filter 104 is configured to perform time integration on a current signal input from the phase comparator 102 and generate a control voltage for the VCO 106. The generated control voltage is input to the VCO 106 from the loop filter 104.

The phase lock oscillator 100 according to an embodiment of the present invention also includes the VCO 106. The VCO 106 is configured to control an oscillation frequency (voltage pulse signal) of an output pulse according to the control voltage input from the loop filter 104. The voltage pulse signal having its oscillation frequency controlled is input to a delay circuit 112 and the divider 108.

The phase lock oscillator 100 according to an embodiment of the present invention also includes the divider 108. The divider 108 is configured to reduce the voltage (voltage pulse signal) output from the VCO 106 to a frequency of 1/N (N being an integer satisfying a relationship of N>0) and input the signal with the reduced frequency to the phase comparator 102.

The phase lock oscillator 100 includes the filter/voltage converting part 110. The filter/voltage converting part 110 is configured to smooth (level) the voltage pulse signal input from the phase comparator 102 with a filter, shift its voltage according to necessity, and input the smoothed voltage pulse signal to the delay circuit 112.

For example, with Formula (3), phase difference is converted to delay time Δt by using the following Formula (4).

Δt=Δφ(t)/ω_{ref} (Formula (4))

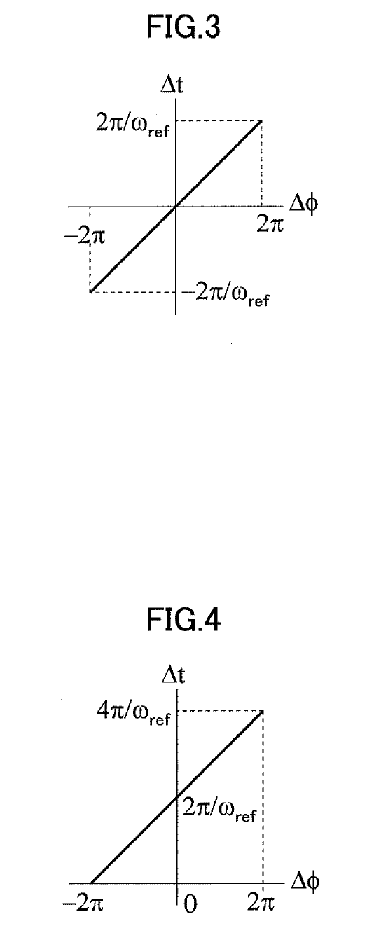

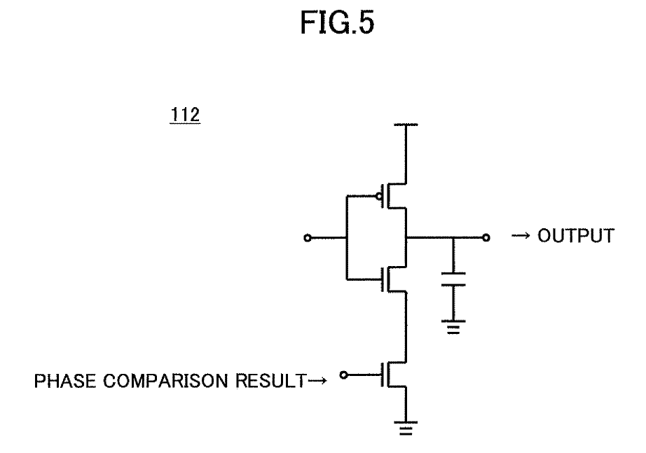

Formula (4) is exemplarily shown in FIG. 3. According to Formula (4), the amount of delay (delay amount) Δt cannot be a negative value in a case where the phase difference is negative. From an aspect of satisfying a relationship of “Δt>0”, it is preferable to apply offset to the delay time. For example, an offset of one cycle (=2n/ω_{ref}) is applied to the Δt. FIG. 4 shows a relationship between Δφ and Δt in a case where an offset of “2n/ω_{ref}” is applied to the Δt.

The phase lock oscillator 100 according to an embodiment of the present invention also includes the delay circuit 112 acting as a delay control part and a delay time controlling part. The delay circuit 112 includes, for example, a voltage control inverter. The delay circuit 112 is configured to instantaneously correct phase offset of the voltage pulse signal output from the VCO 106. FIG. 5 illustrates an example of the voltage control inverter.

For example, a voltage pulse signal output from the VCO 106 is subject to a delay process and output At later. That is, a signal Vₒᵤₜ output from the delay circuit 112 is expressed by the following Formula 5.

$$\begin{matrix}{V}_{out} ( t + Δ t ) = {V}_{vco} ( t ) \\ = sin ( {\int }^{t} {ω}_{vco} d t ) \\ = sin N \{ {ω}_{ref} t + Δ ϕ ( t ) \} \\ = sin N {ω}_{ref} ( t + Δ t )\end{matrix} \qquad ( Formula ( 5 ) )$$

By replacing “t+Δt” with “t”, the following Formula (6) can be obtained.

Vₒᵤₜ(t)=sin Nω_{ref}(t) (Formula (6))

According to Formula (6), it can be understood that an output having a constant frequency can be obtained.

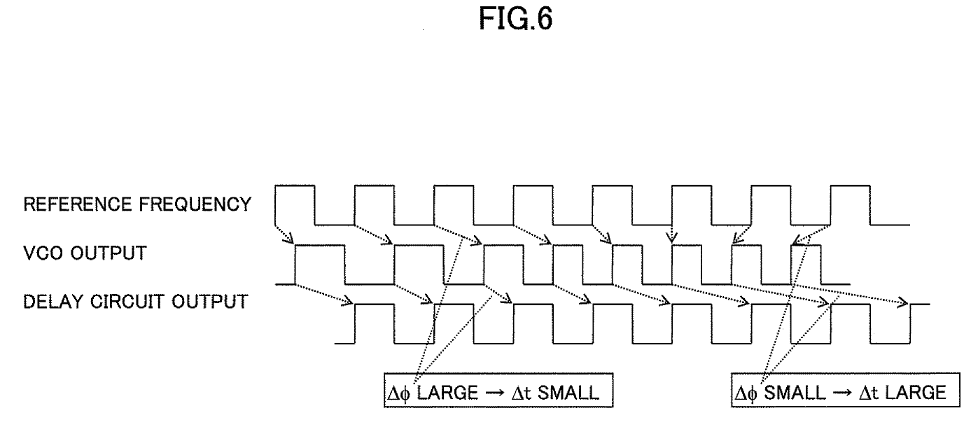

FIG. 6 illustrates a relationship between the amount of phase change (phase change amount) and the amount of correcting the delay amount Δt (delay correction amount) in a case where the dividing ratio N is 1 (N=1). According to FIG. 6, the delay amount Δt is controlled to be small in a case where the phase change amount (phase difference) Δφ is large. Further, the delay amount Δt is controlled to be large in a case where the phase change amount Δφ is small.

With the phase lock oscillator 100 according to an embodiment of the present invention, an oscillation output of the VCO is output through the delay circuit 112 provided outside a PLL part of the phase lock oscillator 100 including the phase comparator 102, the loop filter 104, the VCO 106, and the divider 108. In other words, the phase lock oscillator 100 according to an embodiment of the present invention is a combination of a PLL 150 and the delay circuit 112. The delay circuit 112 is configured to adjust the delay amount according to a phase difference signal between the output of the VCO 106 detected by the phase comparator 102 of the PLL 150 and a reference frequency of a reference signal. As a result, the phase of the output of the VCO 106 can be corrected while restraining phase noise of the PLL 150.

More specifically, in the PLL 150, noise of the PLL 150 itself and/or noise from outside of the PLL 150 causes the frequency of the voltage pulse signal output from the VCO 106 to instantaneously fluctuate. The fluctuation of frequency is detected as a phase difference by the phase comparator 102. The phase comparator 102 is configured to output the phase difference as a voltage pulse signal and is returned N (N being an integer satisfying a relationship of N>0) times the reference frequency by the VCO 106.

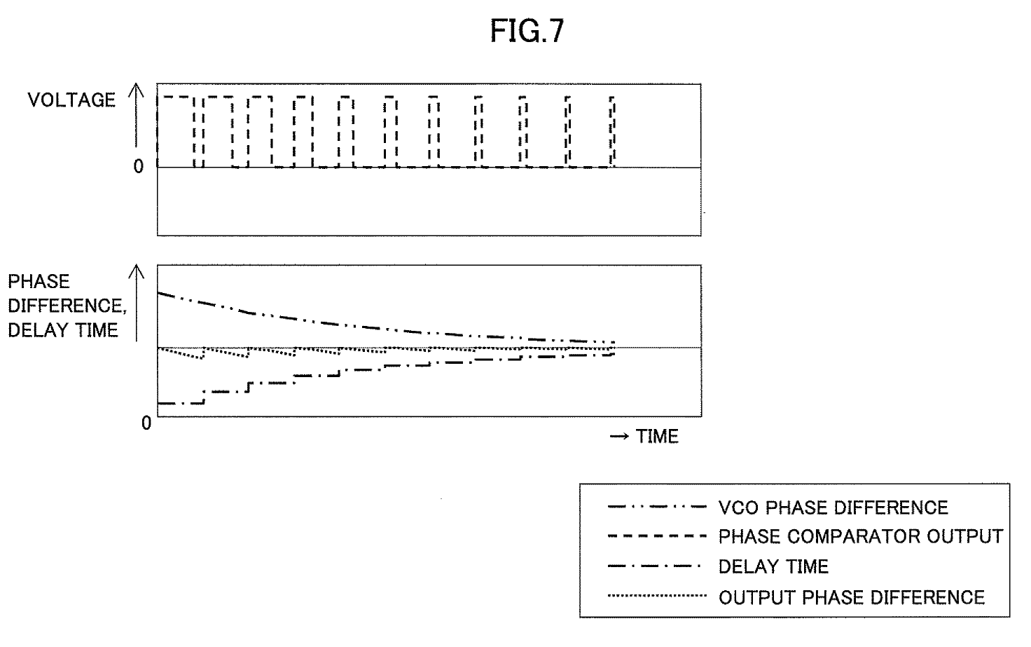

However, in the phase lock oscillator 100 according to an embodiment of the present invention, data (information) of the abrupt phase difference detected by the phase comparator 102 are input to the delay circuit 112. Then, the delay circuit 112 controls the delay amount according to the input data of the abrupt phase difference. Accordingly, abrupt phase offset (instantaneous phase offset) of the voltage signal output from the VCO 106 can be corrected. For example, as illustrated in FIG. 7, at the stage where phase difference is converged toward 0 by the operation of the PLL 150 itself in a case where phase difference occurs between the reference signal and the output of the VCO 16 at time 0, the delay amount decreases in correspondence with the decrease of a phase difference signal output from the phase comparator 102. In FIG. 7, “VCO phase difference” indicates a phase shift (phase offset) with respect to a reference signal of a voltage signal output from the VCO 106 (e.g., abrupt phase offset). Further “output phase difference” indicates a phase shift (phase offset) with respect to a reference signal of a voltage signal output from the delay circuit 112. As a result, the phase difference of the output of the phase lock oscillator 100 according to an embodiment of the present invention can be maintained constant. In the example illustrated in FIG. 7, the delay amount decreases in correspondence with a decrease of phase difference.

With the phase lock oscillator 100 according to the above-described embodiment of the present invention, phase noise of the PLL 150 can be controlled to the level of the reference frequency without affecting the oscillation operation of the PLL 150.

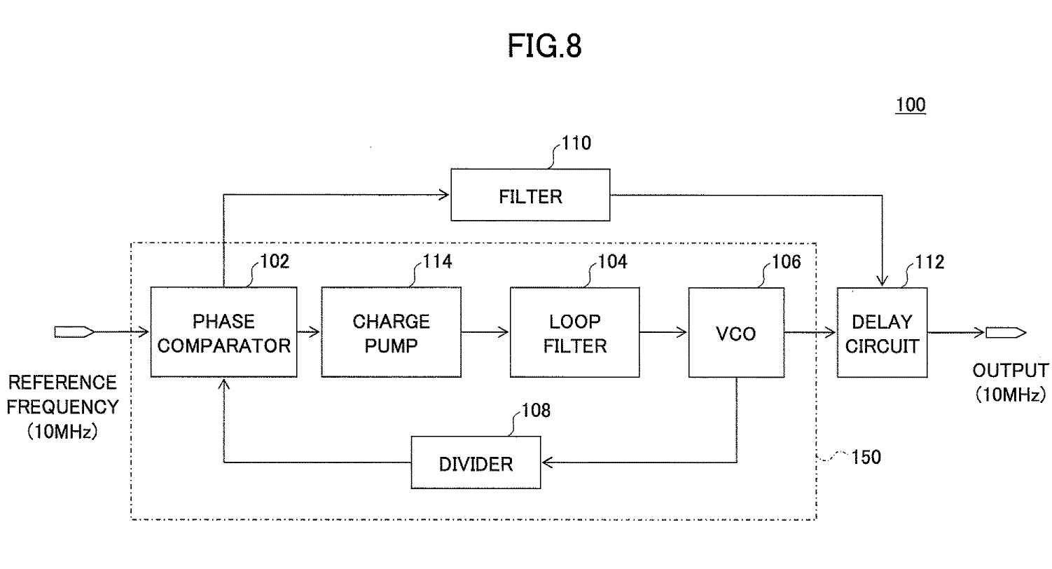

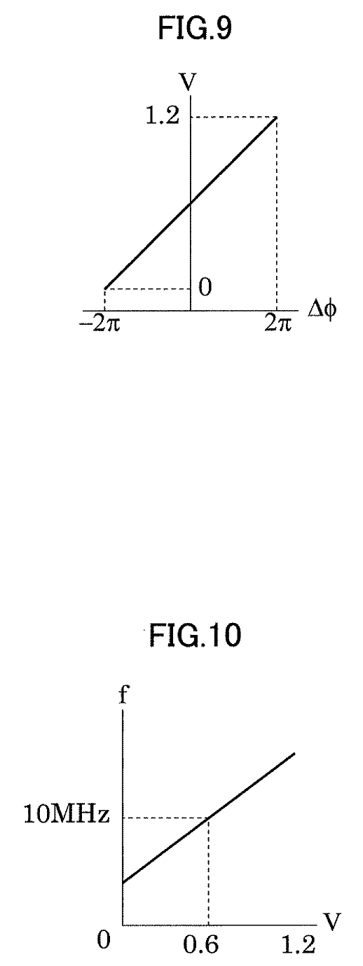

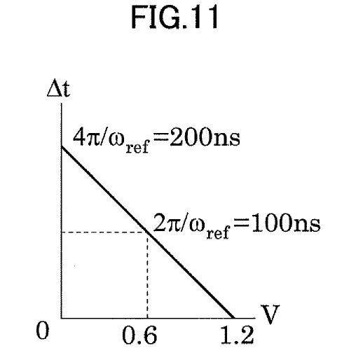

Next, simulation results are described in a case where the reference frequency f_{ref} of a reference signal is 10 MHz and the division ratio N is 1. As illustrated in FIG. 8, the simulation is conducted under a condition where the phase lock oscillator 100 according to an embodiment of the present invention is provided with a charge pump 114. In this embodiment, the phase comparator 102 outputs a phase difference and a voltage pulse signal corresponding to the phase difference to the phase filter 110 and the charge pump 114, respectively. For example, the phase comparator 102 outputs a voltage proportional to the phase difference. FIG. 9 illustrates an example of voltage output from the phase comparator 102 in correspondence with phase difference. The voltage output from the phase comparator 102 becomes higher as phase difference becomes larger. The charge pump 114 outputs a current proportional to the phase difference to the loop filter 104. The loop filter 104 performs time integration on the current (current signal) output from the charge pump 114 and inputs the integrated value as a control voltage to the VCO 106. The VCO 106 oscillates at a frequency controlled by the input control voltage in which the center frequency of the controlled frequency is 10 MHz. The VCO 106 is, for example, configured to oscillate at an oscillation frequency proportional to the input control voltage. FIG. 10 illustrates an example of the oscillation frequency of the VCO 106 controlled in correspondence with control voltage. The delay circuit 112 delays output with respect to input voltage so that delay time decreases in a monotone manner (monotone decrease). The voltage input to the delay circuit 112 is not an integrated value but is a voltage generated by the phase comparator 102 in correspondence with phase difference. FIG. 11 illustrates delays output from the delay circuit 112 in correspondence with input voltage.

The voltage output from the phase comparator 102 becomes higher as the phase difference becomes larger. For example, in a case where the phase difference progressively increases −2n, 0, and 2n, the output voltage correspondingly increases 0 V, 0.6 V, and 1.2 V. The delay amount of the delay circuit 112 becomes smaller in correspondence with the increase of the output voltage of the phase comparator 102. For example, as the output voltage increases 0 V, 0.6 V, and 1.2 V, the delay amount of the delay circuit 112 correspondingly decreases 200 ns, 100 ns, and 0 ns. The filter 110 provided before the delay circuit 112 performs leveling (smoothing) at a predetermined time constant. In a case where the time constant is large, correction cannot be satisfactorily performed in response to an abrupt phase offset (instantaneous phase shift). Therefore, from the aspect of responding to abrupt phase offset, it is preferable to set the time constant substantially equivalent to the oscillation frequency of the VCO 106.

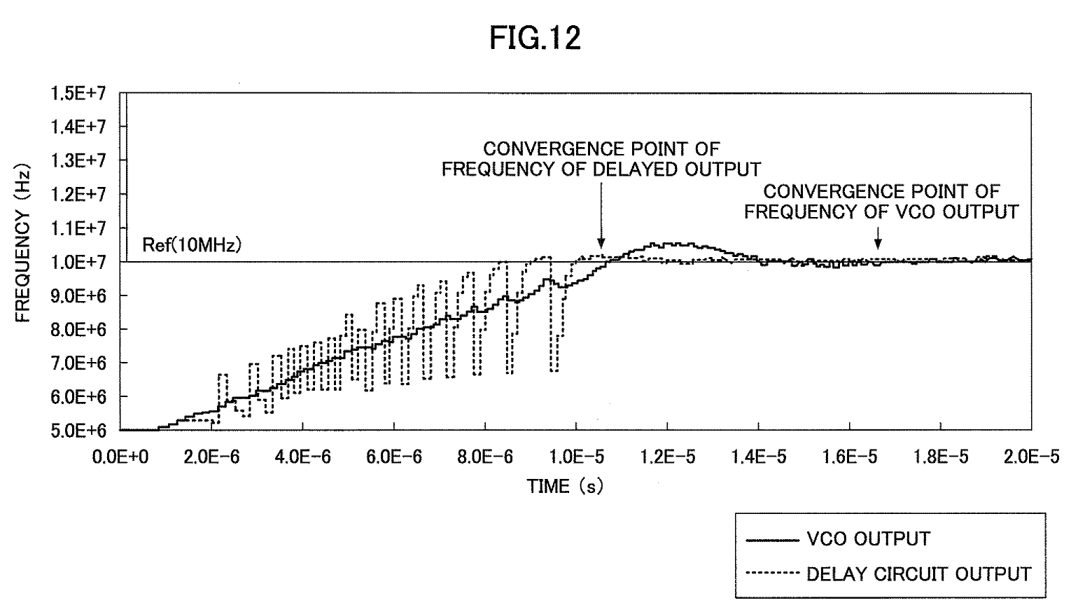

FIG. 12 illustrates simulation results of an operation starting from the initiation of oscillation of the VCO 106 and continuing until the output is locked to 10 MHz. More specifically, FIG. 12 illustrates frequency change of the output of the VCO 106 and that of the output of the delay circuit 112 according to an embodiment of the present invention.

With reference to the example illustrated in FIG. 12, the voltage input to the VCO gradually increases. Accordingly, the oscillation frequency of the VCO 106 increases in correspondence with the increasing input voltage until reaching the vicinity of 10 MHz. The voltage input to the delay circuit becomes higher as the phase difference becomes larger. For example, as described with FIG. 9, in a case where the phase difference increases −2n, 0, and 2n, the voltage input to the delay circuit 112 correspondingly increases 0 V, 0.6 V, and 1.2 V. Furthermore, the delay amount controlled by the delay circuit 112 becomes smaller as the input voltage becomes higher. For example, as described with FIG. 11, in a case where the output voltage increases 0 V, 0.6 V, and 1.2 V, the delay amount of the delay circuit 112 correspondingly decreases 200 ns, 100 ns, and 0 ns.

Because the oscillation frequency of the VCO 106 is low at the beginning of a delay control operation, phase delay increases as time passes. The voltage output from the phase comparator 102 increases as the phase delay increases. That is, the voltage input to the delay circuit 112 increases as the phase delay increases. The delay amount of the delay circuit 112 decreases as the voltage input to the delay circuit 112 increases. In other words, the output of the delay circuit 112 becomes closer to 10 MHz as the delay amount decreases along with the passing of time while the delay amount returns to −2n whenever the phase difference exceeds 2n. In this case, the delay amount becomes 0 ns whenever the delay amount exceeds 200 ns. In other words, the delay amount is also reset to 0 when the phase difference with respect to the reference voltage exceeds 2n. Therefore, frequency temporarily decreases. Nevertheless, the change of frequency does not affect operations of the PLL 150. In a case where phase difference between the VCO 106 and the reference frequency gradually becomes smaller and converges to a point no greater than 2n, no jump of frequency occurs and the phase of the output of the delay circuit 112 converges before the phase of the VCO 106.

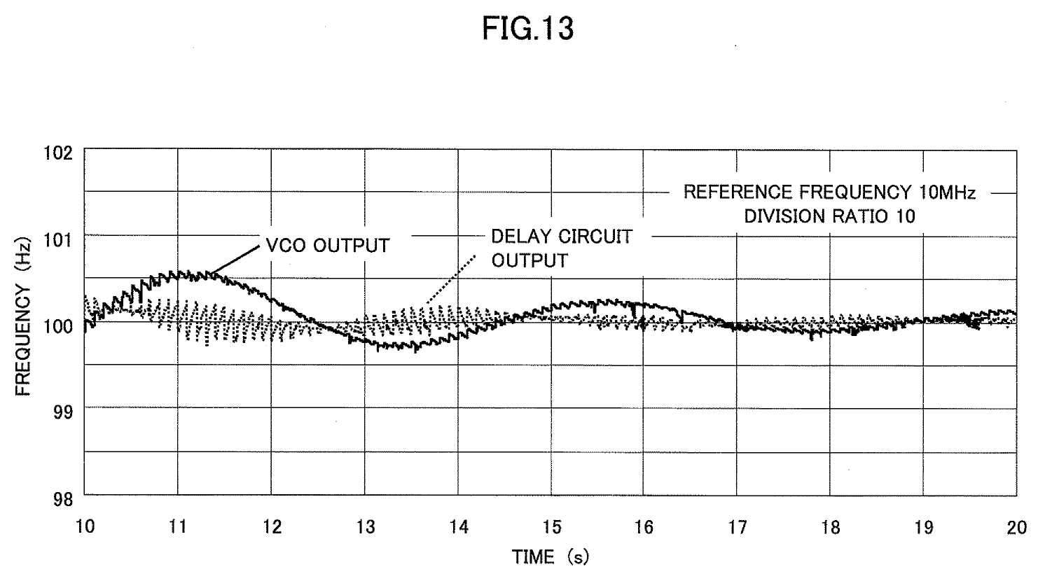

FIG. 13 illustrates an example of output characteristics in a case where noise from outside the phase lock oscillator 100 (in this example, 200 KHz external noise is input to the VCO 106) is input under the conditions where the reference frequency of the reference signal is 10 MHz, and the division ratio is 10. Substantially the same results can be obtained even in a case where the external noise is input to other components of the phase lock oscillator 100. According to FIG. 13, the frequency change of the signal output from the delay circuit 112 is smaller than that of the signal output from the VCO 106. In other words, by providing the delay circuit 112 in the phase lock oscillator 100, frequency change of the VCO 106 can be reduced and a stable output of 10 MHz can be attained.

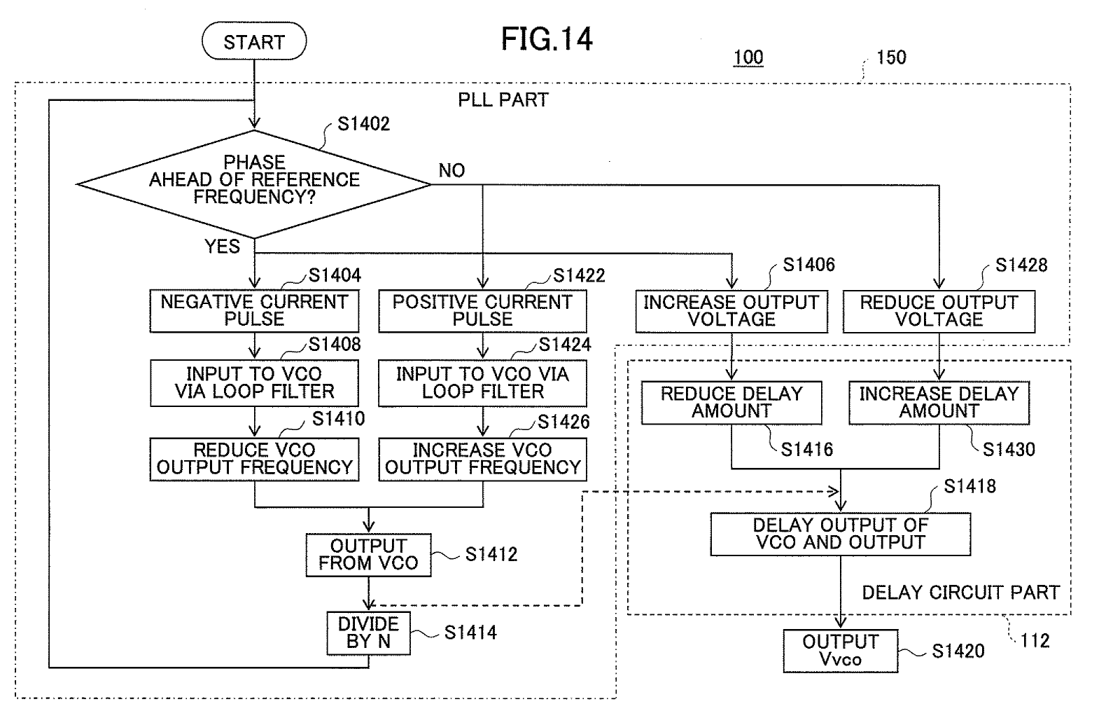

Next, an operation of the phase lock oscillator 100 according to an embodiment of the present invention is described with reference to FIG. 14.

In a case where phase is ahead of (earlier than) the reference frequency (Yes in Step S1402), the phase comparator 102 generates a negative current pulse (Step S1404) and increases output voltage (Step S1406).

Then, the loop filter 104 generates a control voltage by performing time integration on the negative current pulse and inputs the generated control voltage to the VCO 106 (Step S1408). Then, the VCO 106 reduces frequency according to the input control voltage (Step S1410) and outputs a signal having its frequency reduced (Step S1412). Then, the signal output from the VCO 106 is divided by N (Step S1414). Then, the divided signal is input to the phase comparator 102, to thereby return to Step S1402. Then, the above-described processes are repeated.

Meanwhile, the delay circuit 112 reduces the delay amount in correspondence with the increased output voltage of Step S1406 (Step S1416). Then, the delay circuit 112 delays the signal output from the VCO 106 in Step S1412 according to the delay amount (Step S1418). As a result, the phase lock oscillator 100 outputs Vvco (Step S1420).

On the other hand, in a case where phase is behind of (later than) the reference frequency (No in Step S1402), the phase comparator 102 generates a positive current pulse (Step S1422) and reduces output voltage (Step S1428).

Then, the loop filter 104 generates a control voltage by performing time integration on the positive current pulse and inputs the generated control voltage to the VCO 106 (Step S1424). Then, the VCO 106 increases frequency according to the input control voltage (Step S1426) and outputs a signal having its frequency increased (Step S1412). Then, the signal output from the VCO 106 is divided by N (Step S1414). Then, the divided signal is input to the phase comparator 102, to thereby return to Step S1402. Then, the above-described processes are repeated.

Meanwhile, the delay circuit 112 increases the delay amount in correspondence with the reduced output voltage of Step S1428 (Step S1430). Then, the delay circuit 112 delays the signal output from the VCO 106 in Step S1412 according to the delay amount (Step S1418). As a result, the phase lock oscillator 100 outputs Vvco (Step S1420).

With the phase lock oscillator 100 according to the above-described embodiment of the present invention, the phase of the VCO output can be corrected by using a phase difference signal between a VCO output and a reference frequency detected by the phase comparator 102, to thereby reduce phase noise of the PLL 150 to a level substantially equivalent to a reference frequency having relatively small phase noise.

By correcting the phase by using the delay circuit 112 provided at an output part of the phase lock oscillator (local oscillator) 100 for controlling the delay amount corresponding to phase difference with respect to a reference frequency detected by the phase comparator 102 provided inside the phase lock oscillator 100, an oscillation output having a stable phase can be attained.

### Second Embodiment

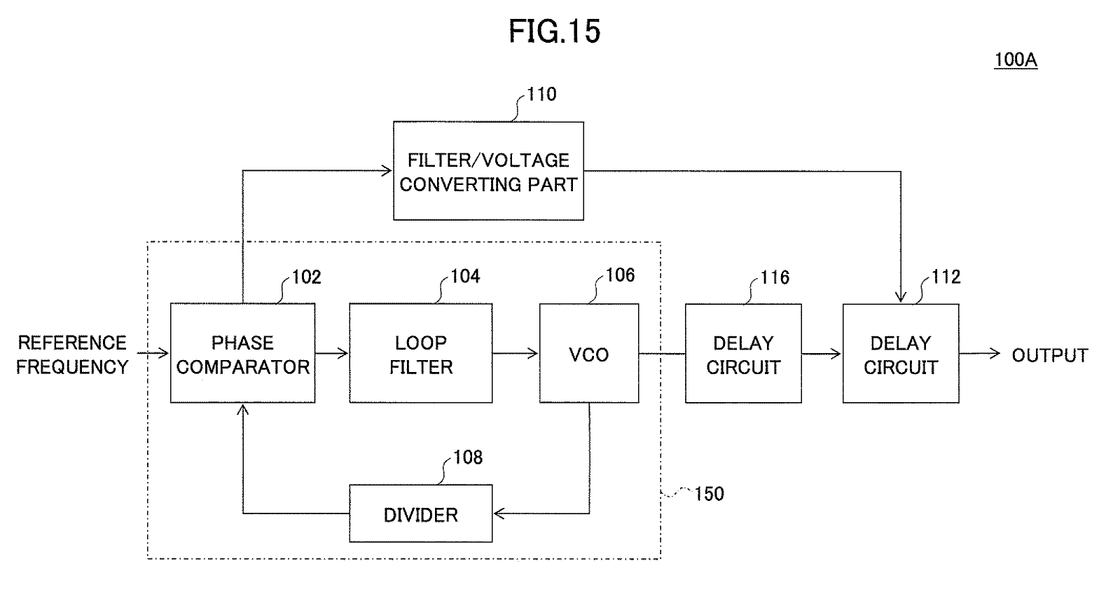

Next, a phase lock oscillator 100A according to a second embodiment of the present invention is described with reference to FIG. 15.

The phase lock oscillator 100A has substantially the same configuration as the above-described phase lock oscillator 100 of the first embodiment except that another delay circuit (delaying part) 116 is provided in the phase lock oscillator 100A. A signal output from the VCO 106 is input to the delay circuit 116. The delay circuit 116 outputs a signal to the delay circuit 112.

In the phase lock oscillator 100 of the first embodiment, the output of the VCO 106 is input to the delay circuit 112 via the divider 108, the phase comparator 102, and the loop filter 104. With this configuration, phase correction performed by a series of processes is delayed one cycle or more from the instant phase offset that occurs in the output of the VCO 106. Therefore, error may occur in a case where phase changes at an interval faster than a reference frequency.

With the phase lock oscillator 100A according to the second embodiment, the delay circuit 116 having a predetermined delay is provided before (in front of) the delay circuit 112. Thereby, the output from the VCO 106 can be matched with the timing of performing delay control with the delay circuit 112. Accordingly, error can be reduced in a case where phase changes at an interval faster than a reference frequency.

### Third Embodiment

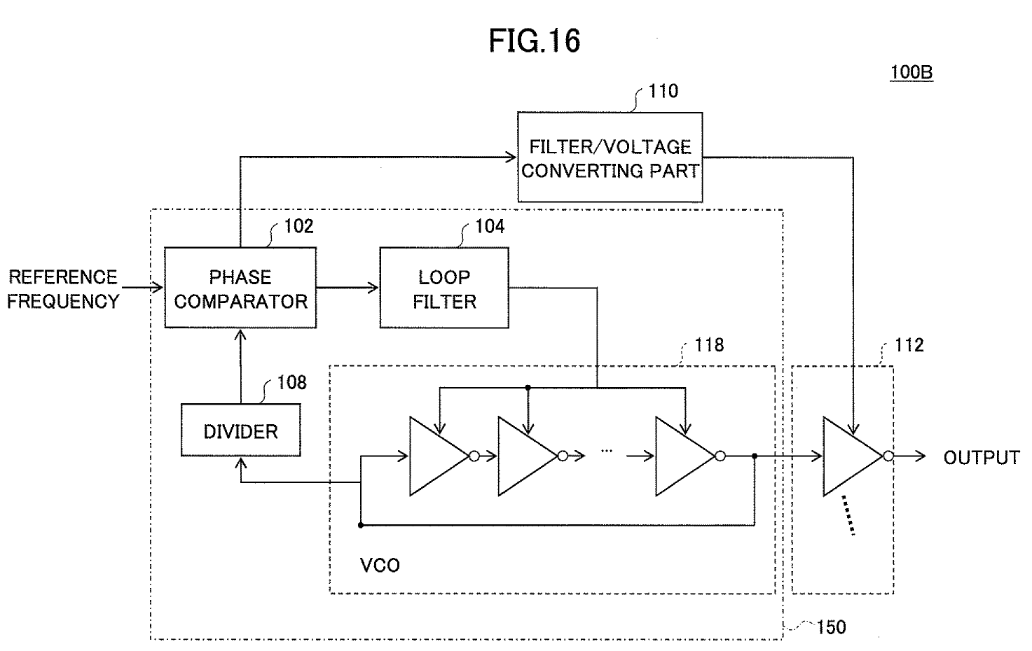

Next, a phase lock oscillator 100B according to a third embodiment of the present invention is described with reference to FIG. 16.

The phase lock oscillator 100B has substantially the same configuration as the phase lock oscillator 100 of the first embodiment except that a VCO 118 configured as a DLL (Delay Locked Loop) is provided in the phase lock oscillator 100B.

With the VCO 118 having the DLL configuration, an oscillation frequency can be selected by controlling a switching time with a bias voltage from an array of inverters forming a delay loop. The same as the PLL, frequency control is performed by controlling the delay amount of the delay loop according to a result of phase comparison by the phase comparator 102. Accordingly, instantaneous phase correction is performed by the delay circuit 112 provided outside the delayed loop of the VCO 118. With the VCO 118 being configured as a DLL, the result of phase comparison is used for frequency control by modifying the delay amount of the internal circuits and for correction of phase outside the DLL configuration. Thereby, phase noise of the PLL 150 can be reduced to a level substantially equivalent to a reference frequency having relatively small phase noise. As a result, a stable output frequency can be attained.

With the phase locked oscillator according to the embodiments of the present invention, phase noise of a PLL can be controlled with a simple method, to thereby improve the performance and/or reduce the cost of wireless communications devices.

Further, the present invention is not limited to these embodiments, but various variations and modifications may be made without departing from the scope of the present invention.

The present application is based on Japanese Priority Application No. 2008-005970 filed on Jan. 15, 2008, with the Japanese Patent Office, the entire contents of which are hereby incorporated herein by reference.

What is claimed is:

1. A phase locked oscillator including a voltage control oscillator and a phase comparator for detecting a phase difference between a phase of an output signal of the voltage control oscillator and a phase of a reference signal and controlling a voltage to be applied to the voltage control oscillator based on the detected phase difference, comprising:
a delay control part configured to apply a variable delay time to the output signal of the voltage control oscillator; and
a delay time controlling part configured to control the delay time according to the detected phase difference.

2. The phase locked oscillator as claimed in claim 1, further comprising:
a filter;
wherein the phase comparator is configured to generate a voltage signal indicating the detected phase difference,
wherein the filter is configured to smooth the voltage signal at a time constant that is substantially equivalent to an oscillation frequency of the voltage control oscillator.

3. The phase locked oscillator as claimed in claim 1, wherein the delay control part is configured to control the delay time so that the delay time equals a single cycle of an oscillation frequency of the voltage control oscillator when the phase difference is 0 and control the delay time so that the change of a delay amount becomes no greater than the single cycle.

4. The phase locked oscillator as claimed in claim 1, wherein the delay time controlling part is configured to control the delay time based on a voltage signal output from the phase comparator according to the phase difference.

5. The phase locked oscillator as claimed in claim 4, wherein the phase comparator is configured to increase an output voltage of the voltage signal in a case where the phase of the output signal of the voltage control oscillator is ahead of the phase of the reference signal, wherein the delay time controlling part is configured to reduce the delay time according to the increased output voltage of the voltage signal.

6. The phase locked oscillator as claimed in claim 1, further comprising:
a delaying part configured to match a timing when the output signal is being output by the voltage control oscillator and a timing when the delay time is being controlled by the delay time controlling part.

7. The phase locked oscillator as claimed in claim 1, wherein the voltage control oscillator includes a DLL (Delay Locked Loop).

8. A wireless communications device comprising:
a phase locked oscillator including
a voltage control oscillator;
a phase comparator for detecting a phase difference between a phase of an output signal of the voltage control oscillator and a phase of a reference signal and controlling a voltage to be applied to the voltage control oscillator based on the detected phase difference;
a delay control part configured to apply a variable delay time to the output signal of the voltage control oscillator; and
a delay time controlling part configured to control the delay time according to the detected phase difference.
